(19) United States
(12) Patent Application Publication
(10) Pub. No.: US 2025/0190027 A1
(43) Pub. Date: Jun. 12, 2025

(54) ELECTRONIC DEVICE

(71) Applicant: Panasonic Intellectual Property Management Co., Ltd., Osaka (JP)

(72) Inventors: Koki YAMAMOTO, Osaka (JP); Keita ENDO, Osaka (JP); Junichi HASEGAWA, Osaka (JP); Shintarou TANAKA, Osaka (JP); Hiroki KAMEZAKI, Osaka (JP); Jun TAKAHASHI, Miyagi (JP)

(73) Assignee: Panasonic Intellectual Property Management Co., Ltd., Osaka (JP)

(21) Appl. No.: 19/055,102

(22) Filed: Feb. 17, 2025

Related U.S. Application Data
(63) Continuation of application No. PCT/JP2023/029269, filed on Aug. 10, 2023.

(30) Foreign Application Priority Data
Sep. 1, 2022 (JP) 2022-139401

(51) Int. Cl. G06F 1/16

(52) U.S. Cl. CPC G06F 1/1656

(57) ABSTRACT

An electronic device includes a panel, a housing having a quadrangular annular shape, the housing facing an outer edge portion of a back surface of the panel and being provided along the outer edge portion, and a sheet positioned between the outer edge portion and the housing. The outer edge portion and the sheet are bonded via a double-sided tape. The housing and the sheet are bonded via an adhesive. The sheet has an extending portion extending to an inner side than the housing as viewed from an orthogonal direction orthogonal to the back surface of the panel.

### TECHNICAL FIELD

The present disclosure relates to an electronic device including a panel and a housing that holds the panel.

### BACKGROUND ART

PTL 1 discloses an electronic device including a panel and a housing that holds the panel. In this electronic device, the panel and the housing are bonded by at least one of an adhesive and a double-sided tape.

### Citation List

### Patent Literature

PTL 1: Unexamined Japanese Patent Publication No. 2013-239972

### SUMMARY OF THE INVENTION

An object of the present disclosure is to provide an electronic device capable of reducing a possibility that a panel is damaged when the panel is separated from a housing.

An electronic device according to one aspect of the present disclosure includes a panel, a housing having a quadrangular annular shape, the housing facing an outer edge portion of a back surface of the panel and being provided along the outer edge portion, and a sheet positioned between the outer edge portion and the housing. The outer edge portion and the sheet are bonded via a double-sided tape, the housing and the sheet are bonded via an adhesive, and the sheet has an extending portion extending to an inner side than the housing as viewed from an orthogonal direction orthogonal to the back surface of the panel.

According to the present disclosure, it is possible to provide the electronic device capable of reducing the possibility that the panel is damaged when the panel is separated from the housing.

### BRIEF DESCRIPTION OF THE DRAWINGS

FIG. 1 is a perspective view illustrating an example of an electronic device according to an exemplary embodiment of the present disclosure as viewed from the front.

FIG. 2 is a perspective view illustrating an example of the electronic device according to the exemplary embodiment of the present disclosure as viewed from the rear.

FIG. 3 is an exploded perspective view of an annular housing, a touch panel, and a liquid crystal unit.

FIG. 4 is a perspective view of the touch panel.

FIG. 5 is a front view of the annular housing.

FIG. 6 is an enlarged view of a portion surrounded by broken line VI in FIG. 5.

FIG. 7 is a front view of the annular housing and the touch panel.

FIG. 8 is a sectional view of the annular housing of FIG. 7 taken along line VIII-VIII.

FIG. 9 is an enlarged view of a portion surrounded by broken line IX in FIG. 8.

### DESCRIPTION OF EMBODIMENT

### Background of Present Disclosure

As disclosed in PTL 1, in an electronic device including a panel and a housing that holds the panel, an adhesive and a double-sided tape are conceivable as means for joining the panel and the housing.

In the electronic device disclosed in PTL 1, a double-sided tape is attached to a partial region of a housing, and an adhesive is applied to a region different from the partial region of the housing. The panel is attached to a double-sided tape and an adhesive.

When the panel is attached to the housing with an adhesive, the panel may be damaged when the panel is separated from the housing for repair or the like. That is, when the panel is attached to the housing with an adhesive, it is difficult to separate the panel from the housing without damaging the panel.

When the panel is attached to the housing by a double-sided tape, it is easy to separate the panel from the housing without damaging the panel. However, the double-sided tape has weaker adhesive strength than the adhesive. Thus, it is advantageous that the attachment area of the double-sided tape when the panel is attached to the housing by the double-sided tape is larger than the application area of the adhesive when the panel is attached to the housing by the adhesive. For example, in a case where the attachment area of the double-sided tape is secured while maintaining the size of the panel, it is conceivable to bring the inner side surface of the housing inward so that the opening of the annular housing becomes small. In this case, a disposition space of the liquid crystal unit and the like arranged so as to be surrounded by the housing is reduced. On the other hand, in a case where the size of the disposition space of the liquid crystal unit or the like is maintained, that is, in a case where the size of the opening of the annular housing is maintained, for example, it is conceivable to bring the outer side surface of the housing toward the outside. In this case, the outer surface of the panel bonded to the housing can also be moved outward. Thus, the housing and the panel are enlarged.

Therefore, the present inventors have found that the above problem can be solved by disposing a sheet between the panel and the housing, bonding the panel and the sheet with a double-sided tape, and bonding the housing and the sheet with an adhesive. That is, the present inventors have found that it is possible to reduce the possibility that the panel is damaged when the panel is separated from the housing while achieving both suppression of an increase in size of the panel and the housing and suppression of a decrease in bonding strength between the panel and the housing, and have reached the following disclosure.

### Exemplary Embodiment

### Overall Configuration

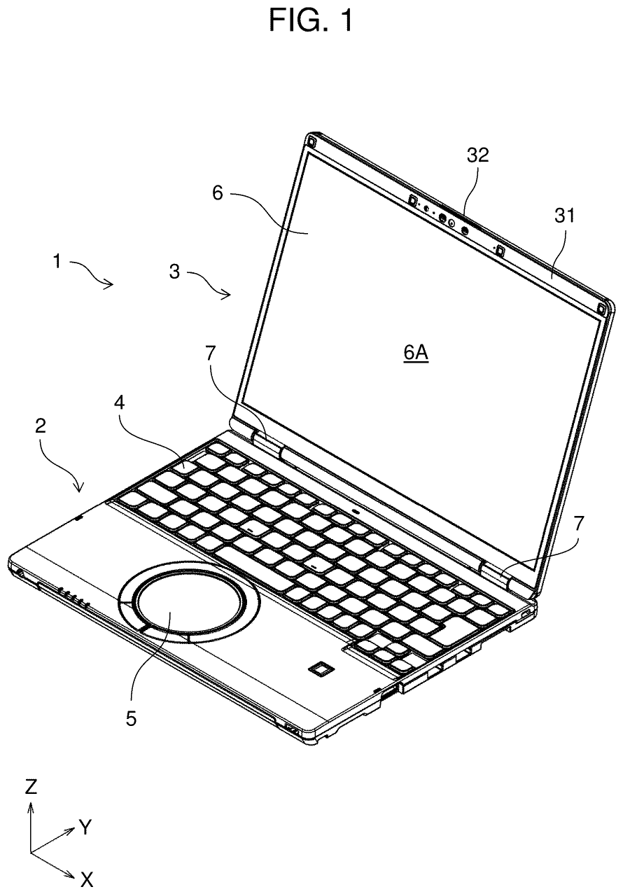

FIG. 1 is a perspective view illustrating an example of an electronic device according to an exemplary embodiment of the present disclosure as viewed from the front. X, Y, and Z directions in the drawing indicate a width direction of first housing 2 (a longitudinal direction of first housing 2), a depth direction (a lateral direction of first housing 2), and a height direction (a thickness direction of first housing 2), respectively. The X, Y, and Z directions are orthogonal to one another.

As illustrated in FIG. 1, electronic device 1 is a notebook personal computer (laptop PC). Electronic device 1 includes first housing 2 and second housing 3. Each of first housing 2 and second housing 3 has a thin box-shaped outer shell, and has a rectangular shape as viewed from an upper surface side.

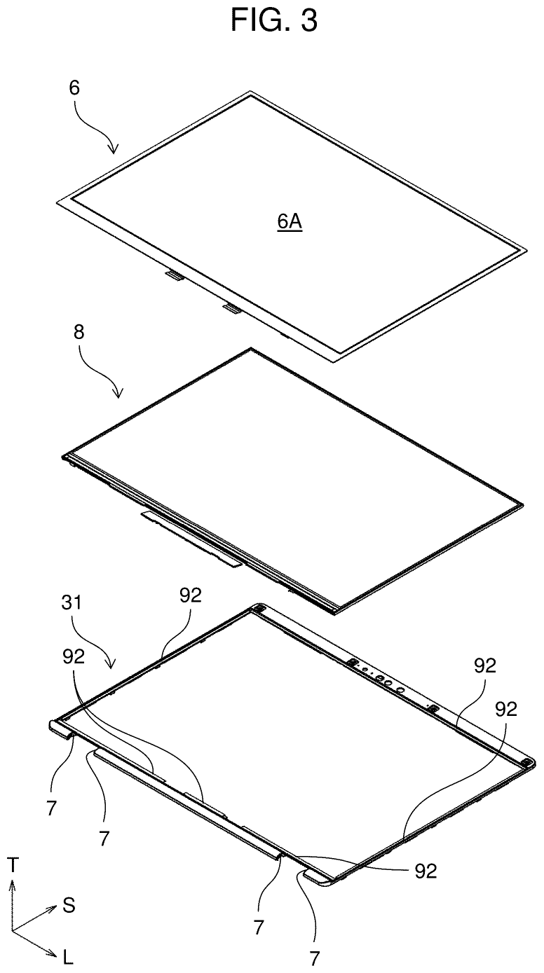

First housing 2 houses keyboard 4 and touch pad 5. In other words, keyboard 4 and touch pad 5 are disposed in first housing 2. Second housing 3 houses touch panel 6 and liquid crystal unit 8 illustrated in FIG. 3. In other words, touch panel 6 and liquid crystal unit 8 are disposed in second housing 3. Touch panel 6 is an example of a panel. Liquid crystal unit 8 is an example of a display unit. In the present specification, keyboard 4 and touch pad 5 may be referred to as input units 4 and 5.

First housing 2 and second housing 3 are coupled via hinges 7. Hinges 7 are provided at end portions of first housing 2 in the depth direction (Y direction). Hinge 7 connects first housing 2 and second housing 3 to each other to be rotatable about a rotation axis parallel to the X direction. At least one of first housing 2 and second housing 3 is rotated by hinges 7, and the electronic device can be opened or closed. Specifically, electronic device 1 can be brought into an open state and a closed state by hinges 7. The “open state” means a state where first housing 2 and second housing 3 are separated from each other and input units 4 and 5 and touch panel 6 are exposed. The “closed state” means a state where first housing 2 and second housing 3 are disposed to face each other in the Z direction, input units 4 and 5 and touch panel 6 face each other, and input units 4 and 5 and touch panel 6 are not exposed.

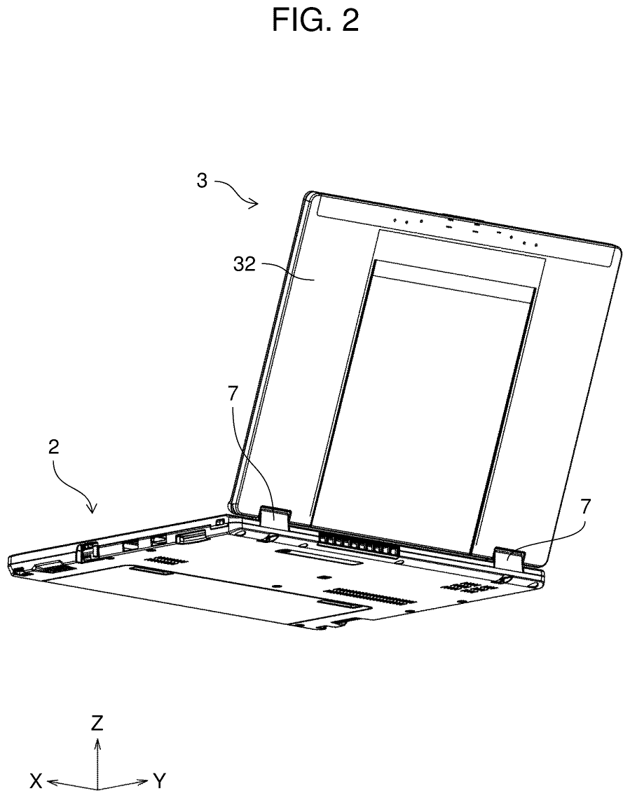

FIG. 2 is a perspective view illustrating an example of the electronic device according to the exemplary embodiment of the present disclosure as viewed from the rear. As illustrated in FIGS. 1 and 2, second housing 3 includes annular housing 31 and plate-shaped housing 32. Annular housing 31 is one example of a housing. Annular housing 31 is supported by plate-shaped housing 32. Annular housing 31 is disposed along an outer edge portion of plate-shaped housing 32. As a result, second housing 3 has a shape in which a portion other than a portion where annular housing 31 is disposed is recessed. Liquid crystal unit 8 and touch panel 6 to be described later are disposed in the recessed portion of second housing 3.

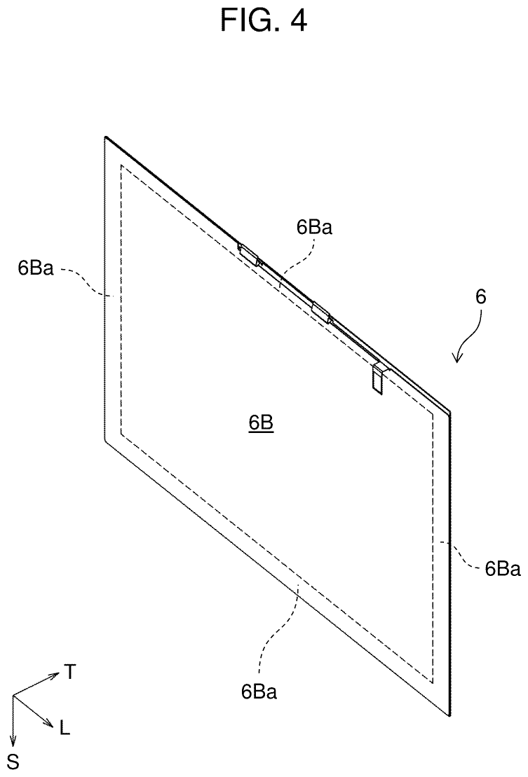

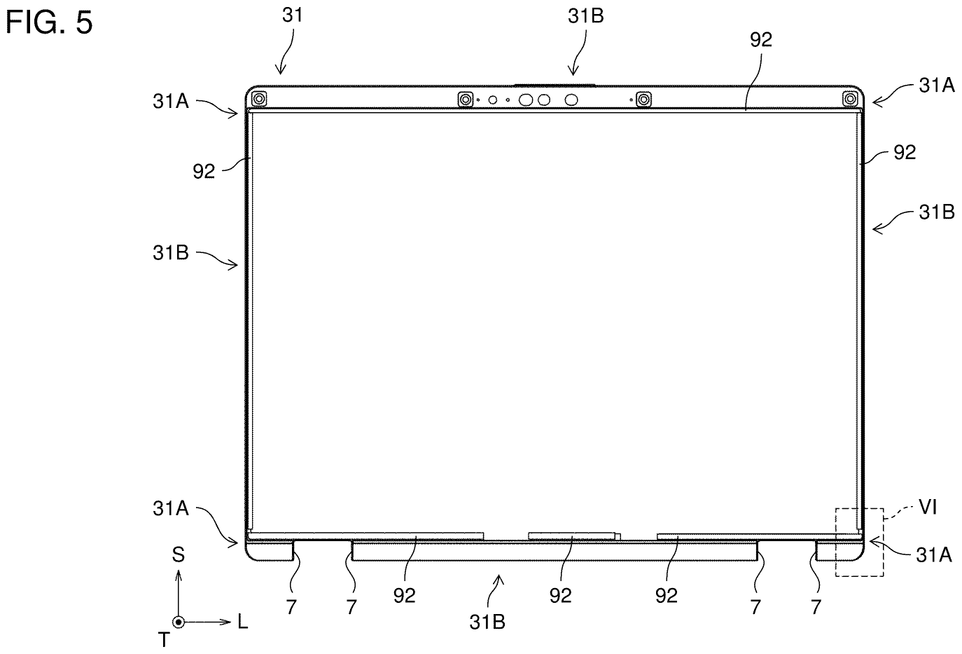

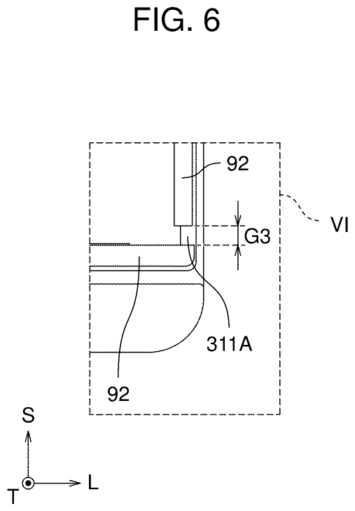

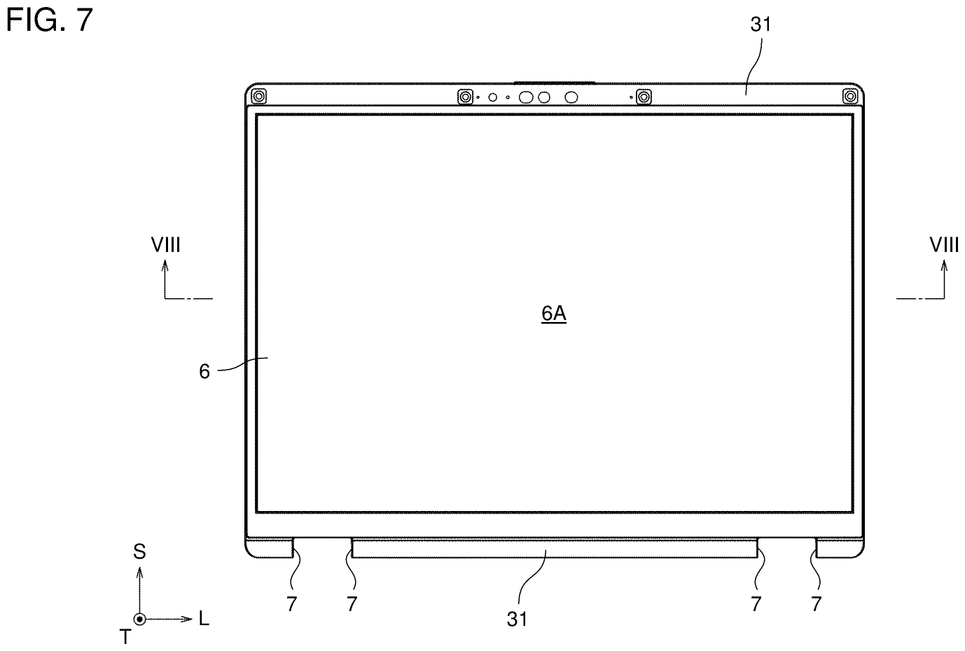

FIG. 3 is an exploded perspective view of the annular housing, the touch panel, and the liquid crystal unit. FIG. 4 is a perspective view of the touch panel. FIG. 5 is a front view of the annular housing. FIG. 6 is an enlarged view of a portion surrounded by broken line VI in FIG. 5. FIG. 7 is a front view of the annular housing and the touch panel.

Hereinafter, configurations of liquid crystal unit 8, touch panel 6, and annular housing 31 will be described, and joining of touch panel 6 and annular housing 31 will be described. L, S, and T directions in FIG. 3 and subsequent drawings indicate a width direction of annular housing 31 (a longitudinal direction of second housing 3), a depth direction (a lateral direction of second housing 3), and a height direction (a thickness direction of second housing 3), respectively. The L, S, and T directions are orthogonal to each other. In the “closed state” described above, the L direction is parallel to the X direction, the S direction is parallel to the Y direction, and the T direction is parallel to the Z direction. In the “open state” described above, the L direction is parallel to the X direction, but the S and T directions are not parallel to the Y and Z directions, respectively. The T direction is an example of an orthogonal direction.

As illustrated in FIG. 3, liquid crystal unit 8 is a device that displays images by liquid crystal. Liquid crystal unit 8 displays images of various colors and shapes. In the present exemplary embodiment, liquid crystal unit 8 has a quadrangular shape as viewed from the T direction. Since the configuration of liquid crystal unit 8 is known, further detailed description is omitted here.

As illustrated in FIGS. 3 and 4, touch panel 6 has front surface 6A and back surface 6B. Back surface 6B is a back surface of front surface 6A. Front surface 6A and back surface 6B spread in the S direction and the L direction, and are orthogonal to the T direction. In the present exemplary embodiment, touch panel 6 has a quadrangular shape as viewed from the T direction.

Liquid crystal unit 8 is disposed to face back surface 6B of touch panel 6 in the T direction. That is, liquid crystal unit 8 is positioned on back surface 6B side of touch panel 6. Touch panel 6 has translucency. Thus, the image displayed by liquid crystal unit 8 is displayed toward an outside of electronic device 1 via touch panel 6.

Touch panel 6 detects a touch operation of a user. Each touch position of touch panel 6 is associated with each function of electronic device 1. Touch panel 6 detects a touch position by the user by a change in pressure, capacitance, or the like. The detected touch position is sent from touch panel 6 to a controller (not illustrated) of electronic device 1. The controller executes a function corresponding to the touch position. The images displayed by liquid crystal unit 8 correspond to different touch positions on touch panel 6. Thus, the user can know an operation executed in a case where touch panel 6 at a position where the image is displayed is touched by referring to the image displayed by liquid crystal unit 8 via touch panel 6.

As illustrated in FIG. 3, annular housing 31 has a quadrangular annular shape as viewed from the T direction. As illustrated in FIGS. 5 and 6, annular housing 31 includes four vertex portions 31A including vertexes of the quadrangle and four side portions 31B including sides of the quadrangle. Each of four side portions 31B connects two adjacent vertex portions 31A.

As illustrated in FIG. 7, in a state where touch panel 6 is bonded to annular housing 31, annular housing 31 surrounds touch panel 6 as viewed from the T direction. Liquid crystal unit 8 is disposed in an internal space formed between touch panel 6 and plate-shaped housing 32. Annular housing 31 surrounds liquid crystal unit 8 as viewed from the T direction.

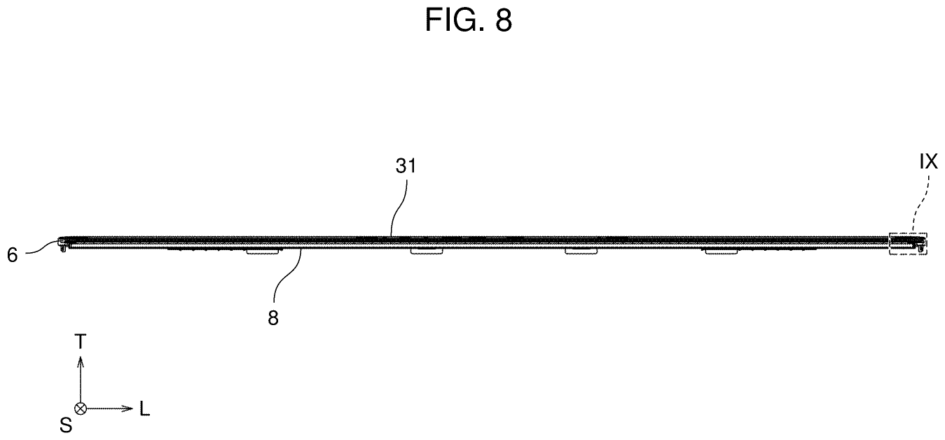

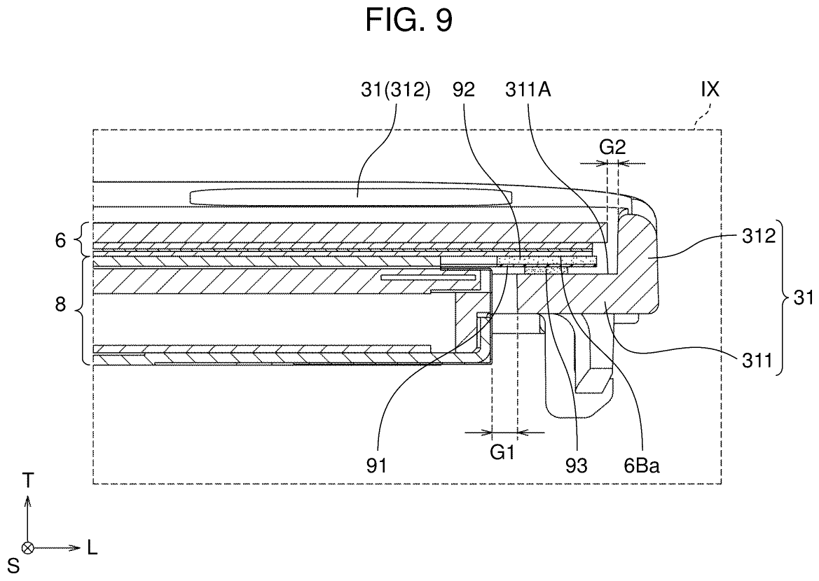

FIG. 8 is a sectional view of the annular housing of FIG. 7 taken along line VIII-VIII. FIG. 9 is an enlarged view of a portion surrounded by a broken line in FIG. 8. As illustrated in FIG. 9, annular housing 31 includes support 311 and protrusion 312. Each of support 311 and protrusion 312 is provided over both vertex portion 31A and side portion 31B. That is, each of support 311 and protrusion 312 has a quadrangular annular shape as viewed from the T direction.

Support 311 is at a position overlapping liquid crystal unit 8 in the T direction. In other words, a position of support 311 in the T direction overlaps with a position of liquid crystal unit 8 in the T direction. In other words, an identical virtual plane that spreads in the L direction and the S direction intersects support 311 and liquid crystal unit 8. Support 311 surrounds liquid crystal unit 8 via gap G1 as viewed from the T direction.

Support 311 is positioned on back surface 6B side of touch panel 6. An inner portion of quadrangular annular support 311 as viewed from the T direction faces outer edge portion 6Ba (see FIG. 4) of back surface 6B of touch panel 6 in the T direction, and is provided along outer edge portion 6Ba. An outer portion of quadrangular annular support 311 as viewed from the T direction is positioned outside touch panel 6 as viewed from the T direction.

Protrusion 312 protrudes in the T direction from the outer portion of quadrangular annular support 311 as viewed in the T direction. Protrusion 312 protrudes in the T direction from surface 311A of support 311 on touch panel 6 side. That is, protrusion 312 is formed in a portion of surface 311A positioned outside touch panel 6 as viewed from the T direction. On the other hand, a portion of surface 311A that is not positioned outside touch panel 6 as viewed from the T direction faces outer edge portion 6Ba of back surface 6B of touch panel 6 in the T direction.

Protrusion 312 surrounds touch panel 6 via gap G2 as viewed from the T direction. Here, in the present exemplary embodiment, gap G1 between liquid crystal unit 8 and support 311 is larger than gap G2 between touch panel 6 and protrusion 312.

Hereinafter, the bonding between touch panel 6 and annular housing 31 will be described.

As illustrated in FIG. 9, annular housing 31 supports touch panel 6 via sheet 91, and is bonded to touch panel 6 via sheet 91. In the T direction, sheet 91 is positioned between annular housing 31 and outer edge portion 6Ba of back surface 6B of touch panel 6. Sheet 91 is made of resin.

Sheet 91 extends to an inner side beyond annular housing 31 as viewed from the T direction. That is, a part of sheet 91 is at a position overlapping support 311 of annular housing 31 as viewed from the T direction, and the other part of sheet 91 is positioned in gap G1 between liquid crystal unit 8 and support 311. A portion other than a part of sheet 91 is an extending portion of sheet 91 extending to the inner side beyond annular housing 31.

Sheet 91 is bonded to outer edge portion 6Ba (see FIG. 4) of back surface 6B of touch panel 6 via double-sided tape 92. Double-sided tape 92 is attached to both a portion of sheet 91 positioned between annular housing 31 and outer edge portion 6Ba of back surface 6B of touch panel 6 and an extending portion of sheet 91 positioned in gap G1.

In the present exemplary embodiment, a thickness of double-sided tape 92 is larger than a thickness of sheet 91. In other words, a length of double-sided tape 92 in the T direction is longer than a length of sheet 91 in the T direction. Any known double-sided tape can be employed as double-sided tape 92 in a condition in which touch panel 6 and sheet 91 can be bonded.

Sheet 91 is bonded to surface 311A of support 311 of annular housing 31 via adhesive 93. Adhesive 93 is applied to a portion of sheet 91 facing annular housing 31 in the T direction.

Adhesive 93 has any thickness, but in the present exemplary embodiment, adhesive 93 is thinner than double-sided tape 92. Any known adhesive can be employed in a condition in which annular housing 31 and sheet 91 can be bonded as adhesive 93. In the present exemplary embodiment, hot melt is employed as adhesive 93.

Sheet 91 is bonded to annular housing 31 along side portion 31B (see FIG. 5) of annular housing 31. As a result, sheet 91 has a quadrangular shape as viewed from the T direction.

As illustrated in FIG. 5, double-sided tape 92 is attached to sheet 91 having a quadrangular shape as viewed in the T direction. Double-sided tape 92 is attached to sheet 91 along each of four side portions 31B. In the present exemplary embodiment, four double-sided tapes 92 are attached to sheet 91. Each of four double-sided tapes 92 is attached to sheet 91 along each of four side portions 31B. Each of four double-sided tapes 92 extends to vertex portion 31A connected to both end portions of side portion 31B. That is, two double-sided tapes 92 attached to sheet 91 along each of two adjacent side portions 31B extend to vertex portion 31A positioned between each of two adjacent side portions 31B. As illustrated in FIG. 6, gap G3 is formed between two double-sided tapes 92 at vertex portion 31A.

In the present exemplary embodiment, at two vertex portions 31A of four vertex portions 31A, gap G3 is formed between two double-sided tapes 92. On the other hand, gap G3 is not formed between two double-sided tapes 92 at remaining two vertex portions 31A among four vertex portions 31A. However, the number of gaps G3 is not limited to two. For example, gap G3 may be formed between two double-sided tapes 92 at all four vertex portions 31A.

### Effects

With electronic device 1 according to the present exemplary embodiment, the following effects can be achieved.

According to the present exemplary embodiment, annular housing 31 and sheet 91 are bonded to each other via adhesive 93 having stronger bonding strength than double-sided tape 92. It is possible to reduce an application area of adhesive 93 on annular housing 31 while maintaining bonding strength between annular housing 31 and sheet 91 as compared with a bonding area of double-sided tape 92 on annular housing 31 in a configuration in which annular housing 31 and sheet 91 are bonded via double-sided tape 92. Thus, it is possible to suppress a decrease in bonding strength between annular housing 31 and sheet 91 while suppressing an increase in size of annular housing 31.

In addition, according to the present exemplary embodiment, outer edge portion 6Ba of back surface 6B of touch panel 6 and sheet 91 are bonded via double-sided tape 92, and sheet 91 extends to the inner side beyond annular housing 31 as viewed from the T direction. Thus, as compared with a configuration in which sheet 91 does not extend to the inner side beyond annular housing 31 as viewed from the T direction, an attachment area of double-sided tape 92 on back surface 6B of touch panel 6 can be increased. As a result, it is possible to suppress a decrease in bonding strength between touch panel 6 and sheet 91. Here, as described above, since annular housing 31 and sheet 91 are bonded via adhesive 93, it is possible to suppress the decrease in bonding strength between annular housing 31 and sheet 91. That is, it is possible to suppress the decrease in bonding strength between touch panel 6 and annular housing 31 bonded via sheet 91.

In addition, according to the present exemplary embodiment, touch panel 6 and sheet 91 are bonded via double-sided tape 92. Thus, when touch panel 6 is separated from sheet 91, that is, when touch panel 6 is separated from annular housing 31, a possibility that touch panel 6 is damaged can be reduced.

According to the present exemplary embodiment, the length of double-sided tape 92 in the T direction is longer than the length of sheet 91 in the T direction. Thus, since the thickness of double-sided tape 92 increases as compared with a configuration in which the length of double-sided tape 92 in the T direction is less than or equal to the length of sheet 91 in the T direction, the bonding strength between touch panel 6 and sheet 91 can be increased.

Normally, in order to avoid collision of liquid crystal unit 8 with annular housing 31 due to positional displacement caused by dropping of electronic device 1 or the like, gap G1 is formed between liquid crystal unit 8 and annular housing 31. According to the present exemplary embodiment, gap G1 between liquid crystal unit 8 and annular housing 31 can be utilized as a space for disposing sheet 91 extending to the inner side beyond annular housing 31.

According to the present exemplary embodiment, gap G1 between liquid crystal unit 8 and support 311 is larger than gap G2 between touch panel 6 and protrusion 312. Thus, as compared with a configuration in which gap G1 is less than or equal to gap G2, a possibility that the position of liquid crystal unit 8 is displaced by the dripping of electronic device 1 or the like and collides with annular housing 31 can be reduced. In addition, a disposition space of sheet 91 in gap G1 can be set to be larger than in the configuration in which gap G1 is less than or equal to gap G2. As a result, the attachment area of double-sided tape 92 on back surface 6B of touch panel 6 can be increased. As a result, it is possible to suppress a decrease in bonding strength between touch panel 6 and sheet 91.

It is easier to peel touch panel 6 from sheet 91 by applying a force to a portion to which double-sided tape 92 is not attached than to peel touch panel 6 from sheet 91 by applying a force to a portion to which double-sided tape 92 is attached. In addition, in a case where annular housing 31 has the quadrangular annular shape, it is easier for the user to apply a force to vertex portion 31A of the annular housing than to apply a force to side portion 31B of annular housing 31.

According to the present exemplary embodiment, at vertex portion 31A of annular housing 31, gap G3 is formed between two double-sided tapes 92 attached to sheet 91 along each of two adjacent side portions 31B. Thus, a force is applied to vertex portion 31A of annular housing 31 to which a force is easily applied, and thus, a force can be applied to a portion of gap G3 to which double-sided tape 92 is not attached. As a result, touch panel 6 can be easily peeled off from sheet 91.

In the present exemplary embodiment, an example in which electronic device 1 includes touch panel 6, that is, an example in which touch panel 6 corresponds to the panel has been described, but the present disclosure is not limited thereto. The panel may be any panel that displays the image displayed by liquid crystal unit 8 toward the outside of electronic device 1. For example, electronic device 1 may include, as the panel, a cover glass having translucency instead of touch panel 6. In this case, electronic device 1 does not have a touch panel function.

In the present exemplary embodiment, an example in which electronic device 1 includes liquid crystal unit 8, that is, an example in which liquid crystal unit 8 corresponds to the display unit has been described, but the present disclosure is not limited thereto. The display unit may be a display unit that displays an image. For example, electronic device 1 may include, as the display unit, a unit that displays an image by organic EL, in other words, organic electro-luminescence (OEL) instead of liquid crystal unit 8.

In the present exemplary embodiment, an example in which sheet 91 is made of resin has been described, but the present disclosure is not limited thereto. For example, sheet 91 may be made of metal.

In the present exemplary embodiment, an example in which liquid crystal unit 8 and touch panel 6 are quadrangular as viewed from the T direction has been described, but liquid crystal unit 8 and touch panel 6 may not be perfect quadrangular. In addition, in the present exemplary embodiment, an example in which annular housing 31 has the quadrangular annular shape as viewed from the T direction has been described, but it is not necessary to have a complete quadrangular annular shape. For example, a shape in which four corners of annular housing 31 are chamfered (C-chamfered or R-chamfered) as viewed from the T direction, and a shape in which a projection protruding in the S direction or the L direction is formed in a part of side portion 31B of annular housing 31 are also included in the “quadrangular annular shape” of annular housing 31. The same applies to the “quadrangle” of liquid crystal unit 8 and touch panel 6. cl Overview of Exemplary Embodiments
(1) An electronic device according to a first aspect of the present disclosure includes a panel, a housing having a quadrangular annular shape, the housing facing an outer edge portion of a back surface of the panel and being provided along the outer edge portion, and a sheet positioned between the outer edge portion and the housing. The outer edge portion and the sheet are bonded via a double-sided tape, the housing and the sheet are bonded via an adhesive, and the sheet has an extending portion extending to an inner side than the housing as viewed from an orthogonal direction orthogonal to the back surface of the panel.
(2) In the electronic device according to (1), a length of the double-sided tape in the orthogonal direction may be longer than a length of the sheet in the orthogonal direction.
(3) The electronic device according to (1) or (2) may further include a display unit that is positioned on a back surface side of the panel, the display unit being surrounded by the housing via a first gap as viewed from the orthogonal direction and displaying an image. The extending portion of the sheet may be positioned in the first gap between the display unit and the housing as viewed from the orthogonal direction.
(4) In the electronic device according to (3), the housing may include a support that is positioned on the back surface side of the panel, the support supporting the panel via the sheet and surrounding the display unit via the first gap as viewed from the orthogonal direction, and a protrusion that protrudes in the orthogonal direction from a surface of the support on the panel side, the protrusion surrounding the panel via a second gap as viewed from the orthogonal direction. The extending portion of the sheet may be positioned in the first gap between the display unit and the support, and the first gap between the display unit and the support may be larger than the second gap between the panel and the protrusion.
(5) In the electronic device according to any one of (1) to (4), the housing may include four vertex portions and four side portions connecting the four vertex portions as viewed from the orthogonal direction, the double-sided tape may be attached to the sheet along the four side portions, the double-sided tape may extend to a vertex portion positioned between two adjacent side portions of the four side portions, and at the vertex portion, a third gap may be provided between a portion of the double-sided tape corresponding to one of the two side portions and a portion of the double-sided tape corresponding to the other of the two side portions.

### Industrial Applicability

The present disclosure is useful for an electronic device (for example, a laptop PC or the like) in which a panel for displaying an image is bonded to a housing.

### Reference Marks in the Drawings

1 electronic device
31 annular housing (housing)
311 support
312 protrusion
31A vertex portion
31B side portion
6 touch panel (panel)
6B back surface
6Ba outer edge portion
8 liquid crystal unit (display unit)
91 sheet
92 double-sided tape
93 adhesive
G1 gap
G2 gap
G3 gap

1. An electronic device comprising:
a panel;
a housing having a quadrangular annular shape, the housing facing an outer edge portion of a back surface of the panel and being provided along the outer edge portion; and
a sheet positioned between the outer edge portion and the housing,
wherein the outer edge portion and the sheet are bonded via a double-sided tape,
the housing and the sheet are bonded via an adhesive, and
the sheet has an extending portion extending to an inner side than the housing as viewed from an orthogonal direction orthogonal to the back surface of the panel.

2. The electronic device according to claim 1, wherein a length of the double-sided tape in the orthogonal direction is longer than a length of the sheet in the orthogonal direction.

3. The electronic device according to claim 1, further comprising:
a display unit that is positioned on a back surface side of the panel, the display unit being surrounded by the housing via a first gap as viewed from the orthogonal direction and displaying an image,
wherein the extending portion of the sheet is positioned in the first gap between the display unit and the housing as viewed from the orthogonal direction.

4. The electronic device according to claim 3,
wherein the housing includes
a support that is positioned on the back surface side of the panel, the support supporting the panel via the sheet and surrounding the display unit via the first gap as viewed from the orthogonal direction, and
a protrusion that protrudes in the orthogonal direction from a surface of the support on the panel side, the protrusion surrounding the panel via a second gap as viewed from the orthogonal direction,
the extending portion of the sheet is positioned in the first gap between the display unit and the support, and
the first gap between the display unit and the support is larger than the second gap between the panel and the protrusion.

5. The electronic device according to claim 1,
wherein the housing includes four vertex portions and four side portions connecting the four vertex portions as viewed from the orthogonal direction,
the double-sided tape is attached to the sheet along the four side portions,
the double-sided tape extends to a vertex portion positioned between two adjacent side portions of the four side portions, and
at the vertex portion, a third gap is provided between a portion of the double-sided tape corresponding to one of the two side portions and a portion of the double-sided tape corresponding to the other of the two side portions.
